(19) United States
(12) Patent Application Publication
(10) Pub. No.: US 2023/0027386 A1
(43) Pub. Date: Jan. 26, 2023

(54) TECHNOLOGIES FOR OVERLAY COMPONENTS FOR A COMPUTE DEVICE

(71) Applicant: Intel Corporation, Santa Clara, CA (US)

(72) Inventors: Prosenjit Ghosh, Portland, OR (US); Tsung-Hsing Hsu, Hillsboro, OR (US); Jordan E. Maslov, Portland, OR (US); Surya Pratap Mishra, Portland, OR (US); James M. Yoder, Beaverton, OR (US)

(73) Assignee: Intel Corporation, Santa Clara, CA (US)

(21) Appl. No.: 17/957,495

(22) Filed: Sep. 30, 2022

(51) Int. Cl. H05K 5/03; H05K 5/02; G06F 1/16

(52) U.S. Cl. CPC H05K 5/03; H05K 5/0204; H05K 5/0226; G06F 1/1656

(57) ABSTRACT

Techniques for overlay components for compute devices are disclosed. In one embodiment, an overlay component on a base portion of a compute device can be moved from a folded or closed position (in which it does not cover the keyboard) to an unfolded or open position (in which it covers part of the keyboard). The base portion includes a touch sensor that allows the overlay component to be used as a touch surface. In another embodiment, an overlay component of a compute device is movable from one position adjacent a display of the compute device to another position adjacent a base of the compute device. The overlay component is electrically switchable from a transparent state to an opaque state, allowing the display to be seen through it in one position and allowing it to be used as an opaque drawing surface in another position.

### BACKGROUND

The traditional layout for a laptop is a lid portion with a display and a base portion with a keyboard and trackpad. Such a layout is convenient, familiar, and functional. Extensions of the traditional layout include tablets with detachable keyboards and a display that can rotate 360° relative to the keyboard. But traditional layouts have a limited number of surfaces and do not take advantage of technological advancements such as foldable electronics and electronic paper displays.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified drawing of at least one embodiment of a compute device with an overlay component.

FIG. 2 is a simplified drawing of at least one embodiment of the compute device of claim 1 with the overlay component unfolded.

FIG. 3 is a cross-sectional view of one embodiment of the compute device of FIG. 1.

FIG. 4 is a cross-sectional view of one embodiment of the compute device of FIG. 1.

FIG. 5 is a cross-sectional view of one embodiment of the compute device of FIG. 1.

FIG. 6 is a simplified block diagram of at least one embodiment of a compute device with an overlay component.

FIG. 7 is a simplified block diagram of at least one embodiment of an environment that may be established by the compute device of FIG. 1.

FIG. 8 is a simplified drawing of at least one embodiment of a compute device with a movable overlay component.

FIG. 9 is a simplified drawing of at least one embodiment of a compute device with a movable overlay component adjacent a display.

FIG. 10 is a simplified drawing of at least one embodiment of a compute device with a movable overlay component adjacent a display.

FIG. 11 is a simplified drawing of at least one embodiment of a compute device with a movable overlay component adjacent a keyboard.

FIG. 12 is a simplified drawing of at least one embodiment of a compute device with a movable overlay component adjacent a keyboard.

FIG. 13 is a cross-sectional view of one embodiment of the compute device of FIG. 8.

FIG. 14 is a simplified drawing of at least one embodiment of a compute device with a movable overlay component adjacent a keyboard and a camera.

FIG. 15 is a cross-sectional view of one embodiment of the compute device of FIG. 8.

FIG. 16 is a side view of one embodiment of the compute device of FIG. 8 in a tent configuration.

FIG. 17 is a side view of one embodiment of the compute device of FIG. 8 in a tablet configuration.

FIG. 18 is a simplified drawing of at least one embodiment of a compute device with a detachable overlay component.

FIG. 19 is a cross-sectional view of one embodiment of the compute device of FIG. 8.

FIG. 20 is a simplified block diagram of at least one embodiment of an environment that may be established by the compute device of FIG. 8.

### DETAILED DESCRIPTION OF THE DRAWINGS

In various embodiments disclosed herein, a compute device may include an overlay component that can be used as, e.g., an additional input surface. The compute device may include circuitry to sense touches on the overlay component, such as by a stylus or by a finger of a user. In some embodiments, the overlay component may include a display, such as an electronic paper display or organic light-emitting diode (OLED) display. In one embodiment, the overlay component is on the base portion of compute device and can unfold to cover part of the keyboard. In another embodiment, the overlay component can move between covering the display and covering the keyboard. In some embodiments, such an overlay component may be passive, allowing for the display to be seen through the overlay component while the overlay component is near the display, while appearing opaque or translucent while the overlay component is near the keyboard. In other embodiments, the overlay component may be electrically switchable between an opaque state and a clear state.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, electromagnetic radiation). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Optical components such as fibers or waveguides may be “connected” if the gap between them is small enough that light can be transferred from one fiber or waveguide to another fiber or waveguide without any intervening optical elements, such as a lens or mirror. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

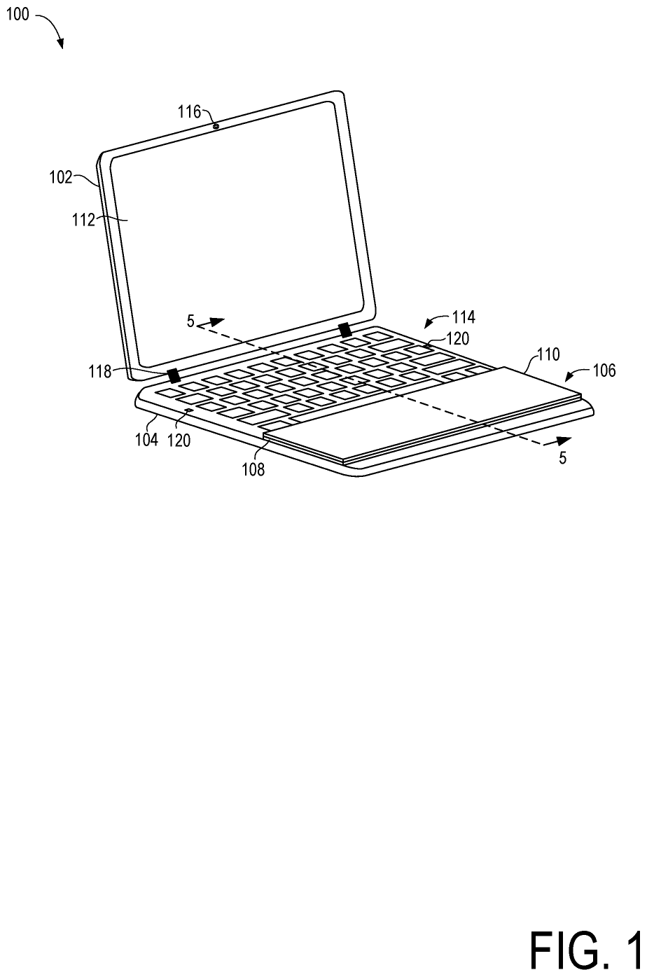

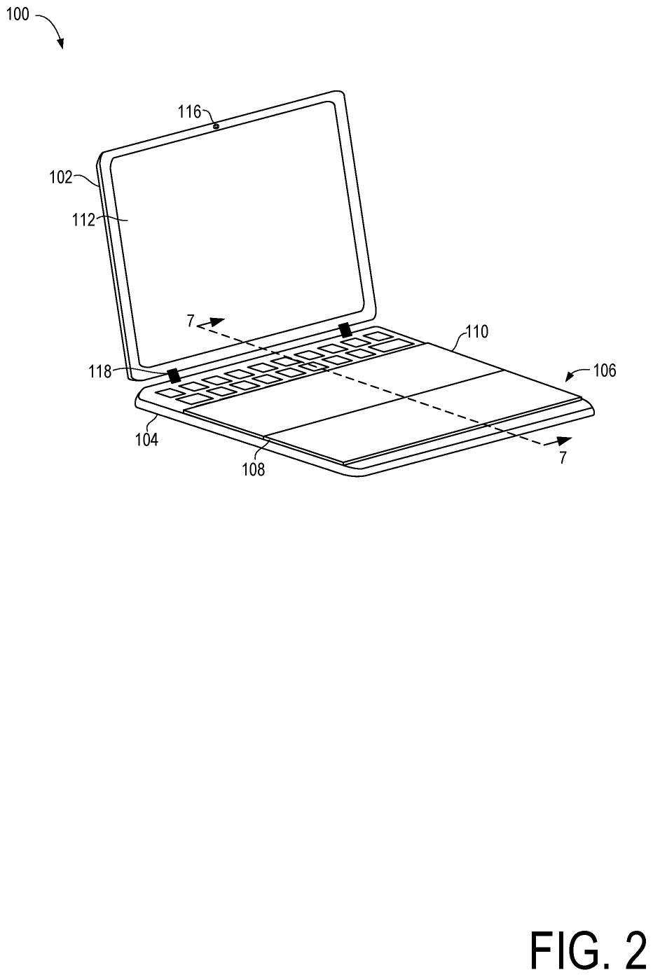

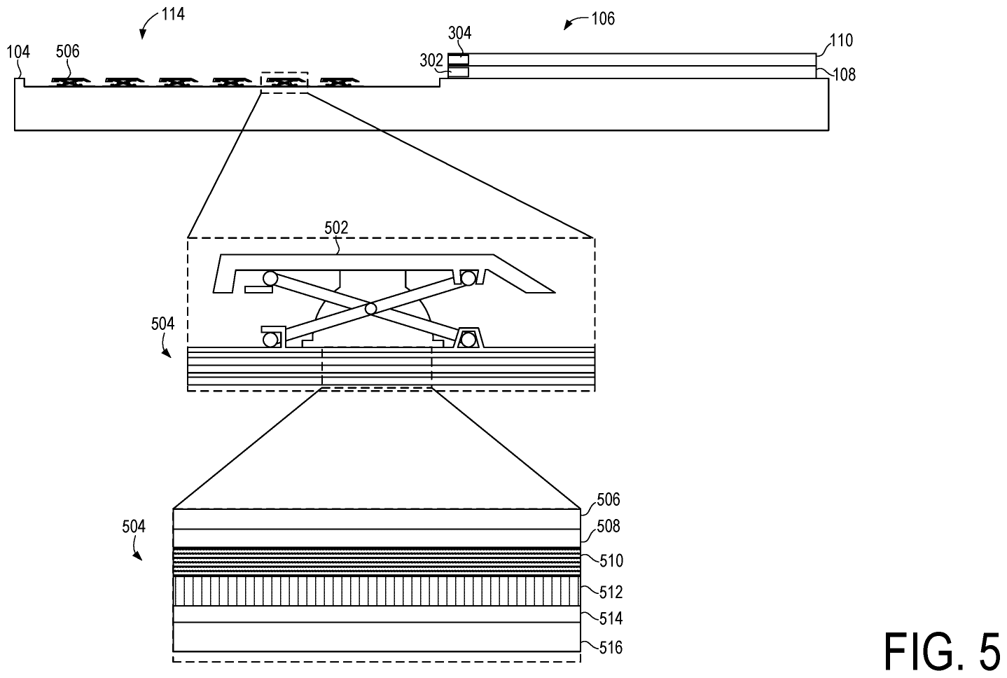

Referring now to FIGS. 1 and 2, an illustrative compute device 100 includes a lid portion 102 and a base portion 104. The lid portion 102 includes a display 112, and the base portion 104 includes a keyboard 114. The compute device 100 includes an overlay component 106. The overlay component 106 includes a bottom overlay section 108 and a top overlay section 110. The top overlay section 110 can unfold from one position stacked on top of the bottom overlay section 108 to another position, in which the top overlay section 110 covers at least part of the keyboard 114, as shown in FIG. 2. As discussed in more detail below, the compute device 100 may include a touch sensor 504 (see FIG. 5) capable of sensing touches on the overlay component 106, both when it is unfolded and folded. A user may use the overlay component 106 as, e.g., a touch pad, a drawing surface, etc.

The illustrative compute device 100 is embodied as a laptop with a clamshell configuration. The illustrative compute device 100 can be in an open configuration (shown in FIGS. 1 and 2) or a closed configuration, with the lid portion 102 positioned on top of the base portion 104 with the display 112 facing downwards toward the base portion 104. Additionally or alternatively, the compute device 100 may be embodied as a laptop with additional configurations. For example, the compute device 100 may be a laptop with a display that can rotate up to 360°, allowing the compute device 100 to be in a book configuration, a tablet configuration, etc. The compute device 100 may be a 2-in-1 device, with a lid portion 102 that can separate from the base portion 104.

The overlay sections 108, 110 may be any suitable material, such as glass, ceramic, plastic, etc. In some embodiments, the overlay sections 108, 110 may be created using electrical discharge machining (EDM). In one embodiment, the overlay sections 108, 110 are passive, with no active electronics. In other embodiments, the overlay sections 108, 110 may have active components in them. For example, in one embodiment, the overlay sections 108, 110 may include an electrophoretic electronic paper display that is visible when the overlay component 106 is open. In such an embodiment, the electronic paper display may include flexible electronics to allow the overlay component 106 to be folded in half in the closed position. The overlay sections 108, 110 may have any suitable thickness, such as 0.1-3 millimeters.

The illustrative lid portion 102 has a display 112. The display 112 may be any suitable size and/or resolution, such as a 5-18 inch display, with a resolution from 340×480 to 3820×2400. The display 112 may use any suitable display technology, such as LED, OLED, QD-LED, electronic paper display, etc. The display 112 may be a touchscreen display. The lid portion 102 may also include a camera 116. The camera 116 may include one or more fixed or adjustable lenses and one or more image sensors. The image sensors may be any suitable type of image sensors, such as a CMOS or CCD image sensor. The camera 116 may have any suitable aperture, focal length, field of view, etc. For example, the camera 116 may have a field of view of 60-110° in the azimuthal and/or elevation directions. In some embodiments, the camera 116 has a field of view that can capture the entire overlay component 106.

In the illustrative embodiment, one or more hinges 118 joins the base portion 104 and the lid portion 102. In the illustrative embodiment, the base portion 104 may include overlay sensors 120 that are configured to sense the position of the overlay component 106, such as by using Hall sensors to detect magnets in the top overlay section 110. In some embodiments, the base portion 104 may include one or more magnets that attract magnets in the overlay component 106 to hold the overlay component 106 in place. In some embodiments, the overlay sensors 120 may sense the position of the overlay component 106 in other ways, such as by reading an RFID tag, monitoring a light level, etc. In other embodiments, the position of the overlay component 106 may not be automatically sensed by the compute device 100. Rather, a user may manually indicate to the compute device 100 that the overlay component 106 is unfolded, or the compute device 100 may not be aware of whether the overlay component 106 is unfolded or not.

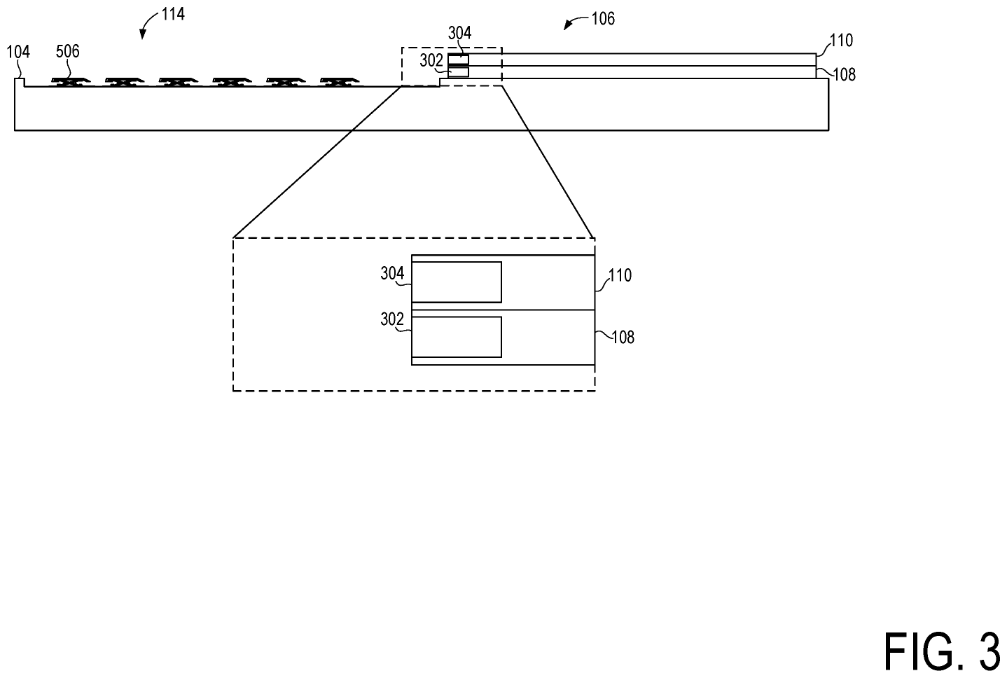

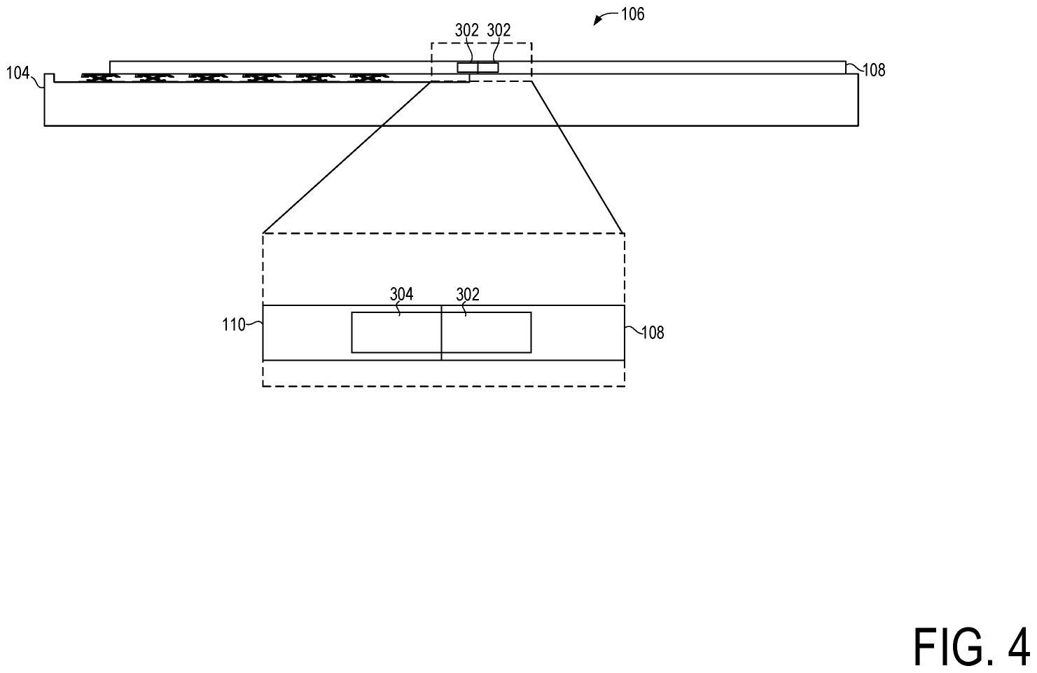

In the illustrative embodiment, the overlay component 106 can unfold using a magnetic hinge in the overlay sections 108, 110. For example, in one embodiment, bottom overlay section 108 includes a magnet 302, and top overlay section 110 includes a magnet 304, as shown in FIGS. 3 and 4. As shown in FIG. 3, when the overlay component 106 is in a folded or closed position, the magnets 302, 304 pull the top overlay section 110 down towards the bottom overlay section 108. For example, the magnetic field in the magnet 304 may be parallel to the page, from left to right, and the magnetic field in the magnet 302 may be parallel to the page, from right to left. The top overlay section 110 can be rotated to place the overlay component 106 in an open position, as shown in FIG. 4. The magnet 304 then has a magnetic field parallel to the page, from right to left, attracting the magnet 302 to keep the overlay sections 108, 110 adjacent. It should be appreciated that the hinge made from the magnets 302, 304 does not require any seam between the overlay sections 108, 110 when the overlay component 106 is unfolded, providing a user a seamless surface on which to work with a smooth transition between the overlay sections 108, 110.

Referring now to FIG. 5, in one embodiment, the base portion 104 of the compute device 100 includes a touch sensor 504 below the keyboard 114 and the overlay component 106. In an illustrative embodiment, the touch sensor 504 is below a keyboard membrane layer 506, which is used to sense strokes of keys 502 of the keyboard 114. The touch sensor 504 has a metal mesh or grid sensing layer that includes a horizontal sensing layer 510 and a vertical sensing layer 512. An optically clear adhesive layer 508 joins the horizontal sensing layer 510 to the keyboard membrane layer 506, and another optically clear adhesive layer 514 joins the vertical sensing layer 512 to a keyboard backlight layer 516. The horizontal sensing layer 510 and the vertical sensing layer 512 work together to detect positions of objects up to 10 millimeters above the touch sensor 504. The touch sensor 504 may detect, e.g., a stylus or a finger of a user, both when hovering over the overlay component 106 as well as when touching the overlay component 106, either when the overlay component 106 is folded or unfolded. The touch sensor 504 may allow the overlay component 106 to be used as, e.g., a trackpad, a digitizer surface, a drawing surface, etc. In some embodiments, the overlay component 106 may include pigmented molecules that are visible when pressure is applied to the overlay component 106, allowing a user to draw on the overlay component 106.

Each of the horizontal sensing layer 510 and the vertical sensing layer 512 may have any suitable thickness, such as 10-30 micrometers. Each of the optically adhesive layers 508, 514 may have any suitable thickness, such as 30-100 micrometers.

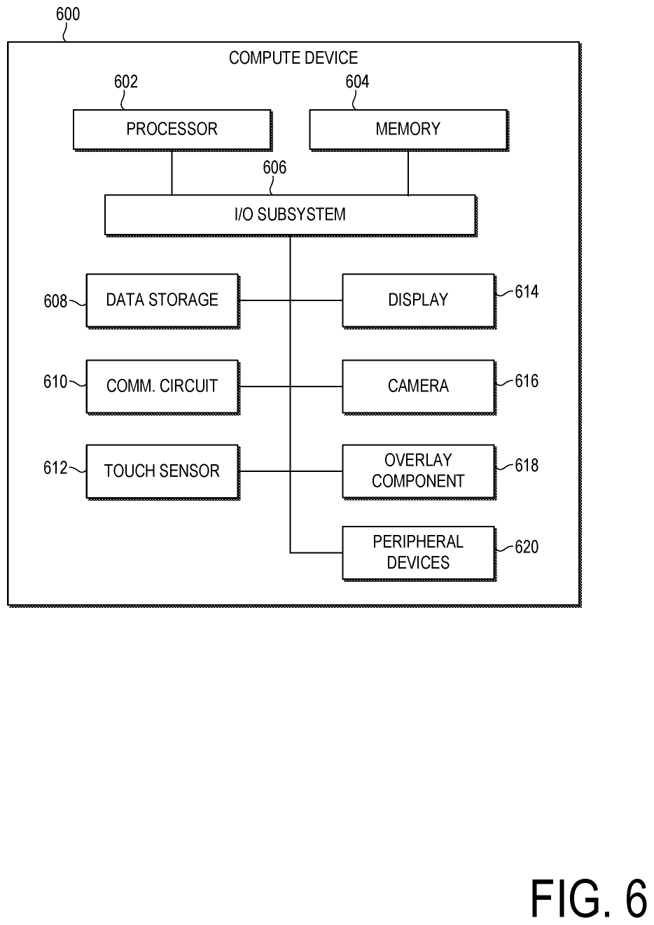

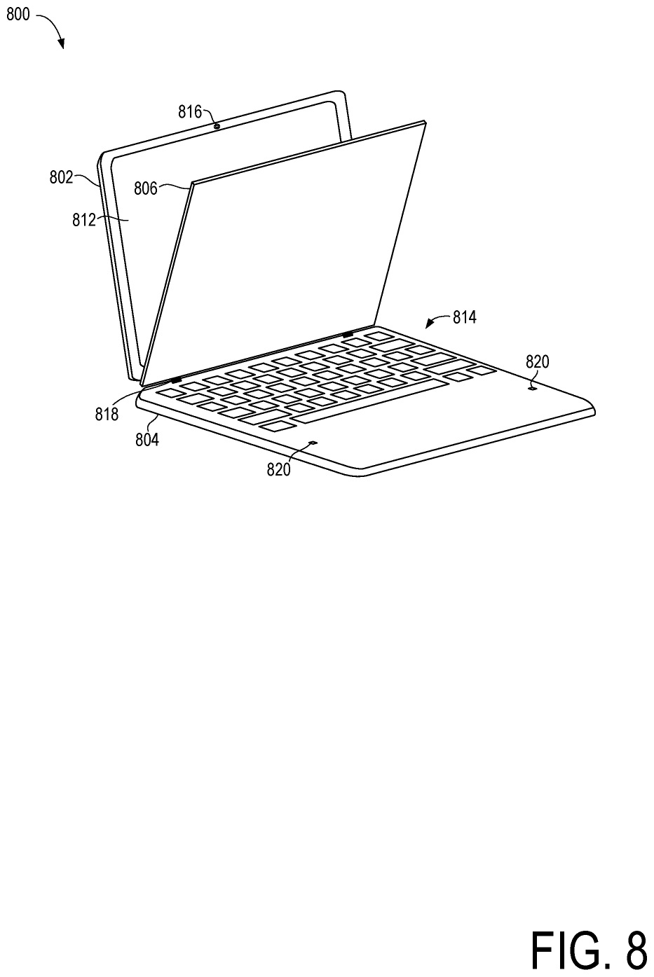

Referring now to FIG. 6, in one embodiment, a compute device 600 for use with an overlay component 106 or overlay component 806 (see FIG. 8) is shown. The compute device 600 may be embodied as any suitable embodiment of the compute device 100 described above or the compute device 800 described below. The compute device 600 may be embodied as any type of compute device. For example, the compute device 600 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a networked computer, a wearable computer, a handset, a messaging device, a camera device, and/or any other compute device. In some embodiments, the compute device 600 may be located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

The illustrative compute device 600 includes a processor 602, a memory 604, an input/output (I/O) subsystem 606, data storage 608, a communication circuit 610, a touch sensor 612, a display 614, a camera 616, an overlay component 618, and one or more peripheral devices 620. In some embodiments, one or more of the illustrative components of the compute device 600 may be incorporated in, or otherwise form a portion of, another component. For example, the memory 604, or portions thereof, may be incorporated in the processor 602 in some embodiments. In some embodiments, one or more of the illustrative components may be physically separated from another component.

The processor 602 may be embodied as any type of processor capable of performing the functions described herein. For example, the processor 602 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 604 may be embodied as any type of volatile or non-volatile memory or data storage capable of performing the functions described herein. In operation, the memory 604 may store various data and software used during operation of the compute device 600 such as operating systems, applications, programs, libraries, and drivers. The memory 604 is communicatively coupled to the processor 602 via the I/O subsystem 606, which may be embodied as circuitry and/or components to facilitate input/output operations with the processor 602, the memory 604, and other components of the compute device 100. For example, the I/O subsystem 606 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 606 may connect various internal and external components of the compute device 600 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 606 may form a portion of a system-on-a-chip (SoC) and be incorporated, along with the processor 602, the memory 604, and other components of the compute device 100 on a single integrated circuit chip.

The data storage 608 may be embodied as any type of device or devices configured for the short-term or long-term storage of data. For example, the data storage 608 may include any one or more memory devices and circuits, memory cards, hard disk drives, solid-state drives, or other data storage devices.

The communication circuit 610 may be embodied as any type of interface capable of interfacing the compute device 600 with other compute devices, such as over one or more wired or wireless connections. In some embodiments, the communication circuit 610 may be capable of interfacing with any appropriate cable type, such as an electrical cable or an optical cable. The communication circuit 610 may be configured to use any one or more communication technology and associated protocols (e.g., Ethernet, Bluetooth®, Wi-Fi®, WiMAX, near field communication (NFC), etc.). The communication circuit 610 may be located on silicon separate from the processor 602, or the communication circuit 610 may be included in a multi-chip package with the processor 602, or even on the same die as the processor 602. The communication circuit 610 may be embodied as one or more add-in-boards, daughtercards, network interface cards, controller chips, chipsets, specialized components such as a field programmable gate array (FPGA) or application specific integrated circuit (ASIC), or other devices that may be used by the compute device 602 to connect with another compute device. In some embodiments, communication circuit 610 may be embodied as part of a system-on-a-chip (SoC) that includes one or more processors, or included on a multichip package that also contains one or more processors. In some embodiments, the communication circuit 610 may include a local processor (not shown) and/or a local memory (not shown) that are both local to the communication circuit 610. In such embodiments, the local processor of the communication circuit 610 may be capable of performing one or more of the functions of the processor 602 described herein. Additionally or alternatively, in such embodiments, the local memory of the communication circuit 610 may be integrated into one or more components of the compute device 602 at the board level, socket level, chip level, and/or other levels.

The camera 616 may be similar to the camera 116, a description of which will not be repeated in the interest of clarity. The overlay component 618 may be embodied as any suitable embodiment of the overlay component 106 described above or the overlay component 806 described below, a description of which will not be repeated in the interest of clarity. In some embodiments, the overlay component 618 may be a passive device that is not directly connected to other components of the compute device 600. In other embodiments, the overlay component 618 may be an active device that is directly connected to one or more other components of the compute device 600.

In some embodiments, the compute device 600 may include other or additional components, such as those commonly found in a compute device. For example, the compute device 600 may also have peripheral devices 620, such as a keyboard, a mouse, a speaker, an external storage device, etc. In some embodiments, the compute device 600 may be connected to a dock that can interface with various devices, including peripheral devices 620. The compute device 600 may include several additional components, such as a battery, one or more antennas, one or more connectors (such as one or more USB2 connectors, one or more USB3 connectors, an SD card slot, a headphone and/or microphone jack, a power connector, etc.), etc. Each of those various components may be in the lid portion 102 and/or the base portion 104, as appropriate.

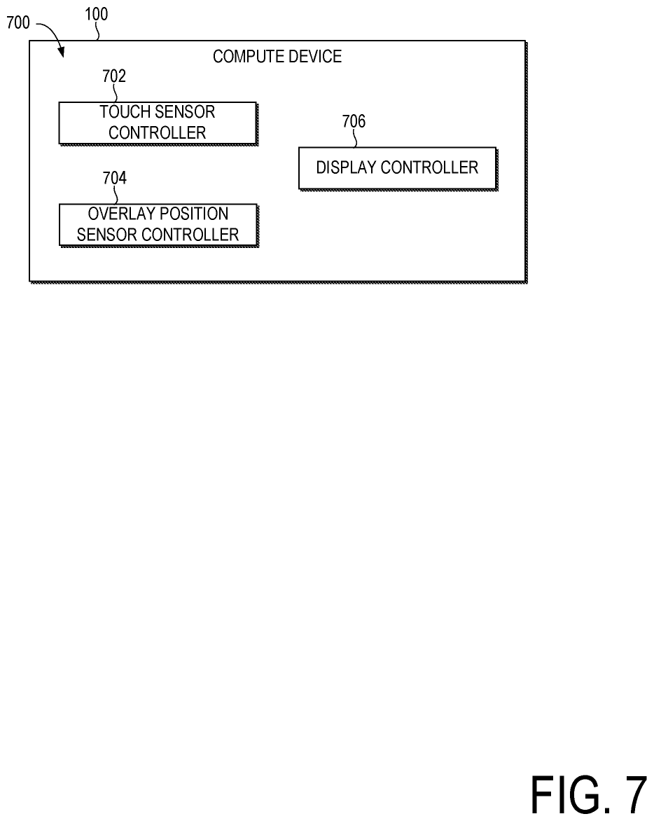

Referring now to FIG. 7, in an illustrative embodiment, the compute device 100 establishes an environment 700 during operation. The illustrative environment 700 includes a touch sensor controller 702, an overlay position sensor controller 704, and a display controller 706. The various modules of the environment 700 may be embodied as hardware, software, firmware, or a combination thereof. For example, the various modules, logic, and other components of the environment 700 may form a portion of, or otherwise be established by, the processor 602, the memory 604, the data storage 608, or other hardware components of the compute device 100. As such, in some embodiments, one or more of the modules of the environment 700 may be embodied as circuitry or collection of electrical devices (e.g., touch sensor controller circuitry 702, overlay position sensor controller circuitry 704, display controller circuitry 706, etc.). It should be appreciated that, in such embodiments, one or more of the circuits (e.g., the touch sensor controller circuitry 702, the overlay position sensor controller circuitry 704, the display controller circuitry 706, etc.) may form a portion of one or more of the processor 602, the memory 604, the I/O subsystem 606, the data storage 608, and/or other components of the compute device 100. For example, in some embodiments, some or all of the modules may be embodied as the processor 602, as well as the memory 604 and/or data storage 608 storing instructions to be executed by the processor 602. Additionally, in some embodiments, one or more of the illustrative modules may form a portion of another module and/or one or more of the illustrative modules may be independent of one another. Further, in some embodiments, one or more of the modules of the environment 700 may be embodied as virtualized hardware components or emulated architecture, which may be established and maintained by the processor 602 or other components of the compute device 100. It should be appreciated that some of the functionality of one or more of the modules of the environment 700 may require a hardware implementation, in which case embodiments of modules that implement such functionality will be embodied at least partially as hardware.

The touch sensor controller 702, which may be embodied as hardware, firmware, software, virtualized hardware, emulated architecture, and/or a combination thereof as discussed above, is configured to sense touches and/or hover positions of objects such as a stylus or finger of a user. The touch sensor controller 702 may sense touches and hovers over or on the overlay component 106 when the overlay component 106 is in a folded/closed position or an unfolded/open position. The touch sensor controller 702 may interpret data from the touch sensor differently depending on the configuration of the overlay component 106. For example, if the overlay component 106 is unfolded, the touch sensor controller 702 may interpret a position of an object at the position of the top overlay section 110 as a touch on the top overlay section. If the overlay component 106 is in a folded/closed position, the touch sensor controller 702 may interpret a position of an object at the same spot as a hover over the keyboard 114 rather than a touch on the top overlay section 110.

The overlay position sensor controller 704, which may be embodied as hardware, firmware, software, virtualized hardware, emulated architecture, and/or a combination thereof as discussed above, is configured to sense the position of the overlay component 106. The overlay position sensor controller 704 is configured to interface with the overlay sensors 120 that sense the presence of the overlay component 106. The overlay position sensor controller 704 may provide an indication to other components of the compute device 100, which may then change function based on the overlay component 106 being opened or closed. For example, a particular application, input interface, or display parameter may be changed in response to the overlay component 106 being opened or closed.

The display controller 706, which may be embodied as hardware, firmware, software, virtualized hardware, emulated architecture, and/or a combination thereof as discussed above, is configured to control the display 112 and/or an electronic paper display on the overlay component 106. In one embodiment, when the overlay component 106 is opened and being used as an electronic paper display, the display 112 may be turned off to save power.

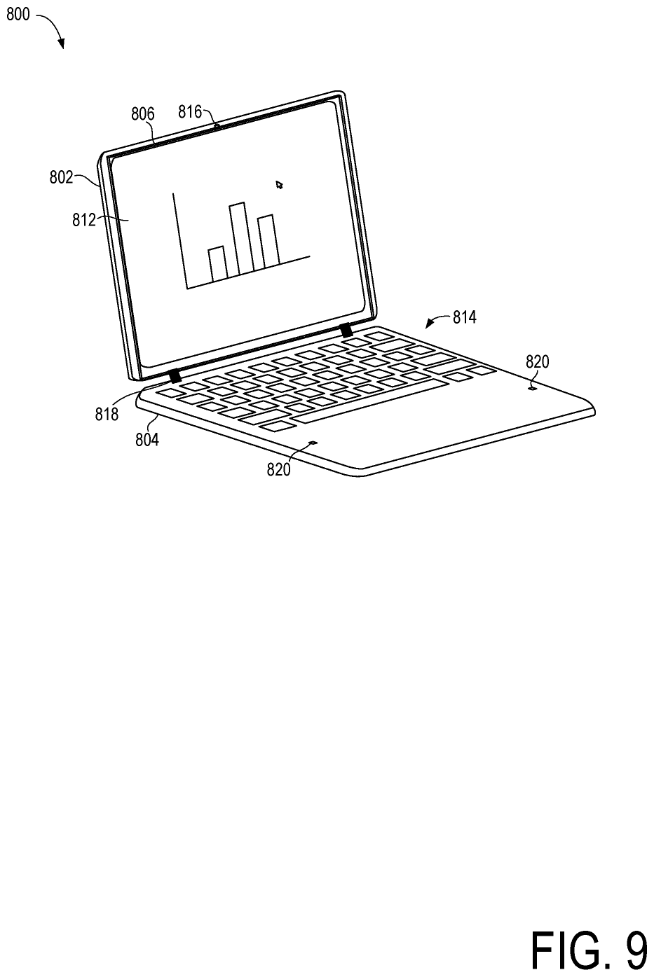

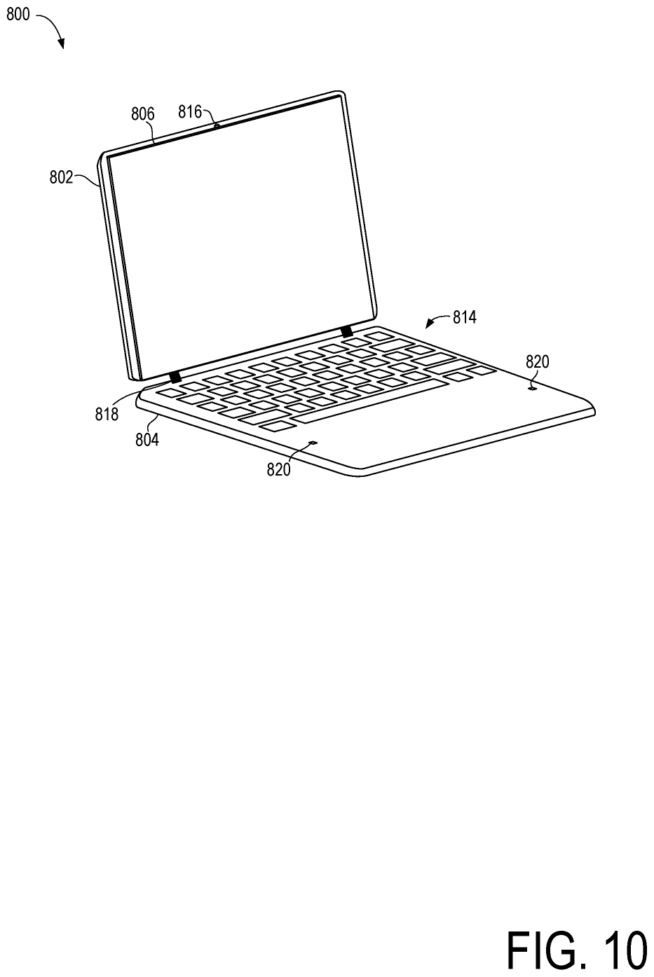

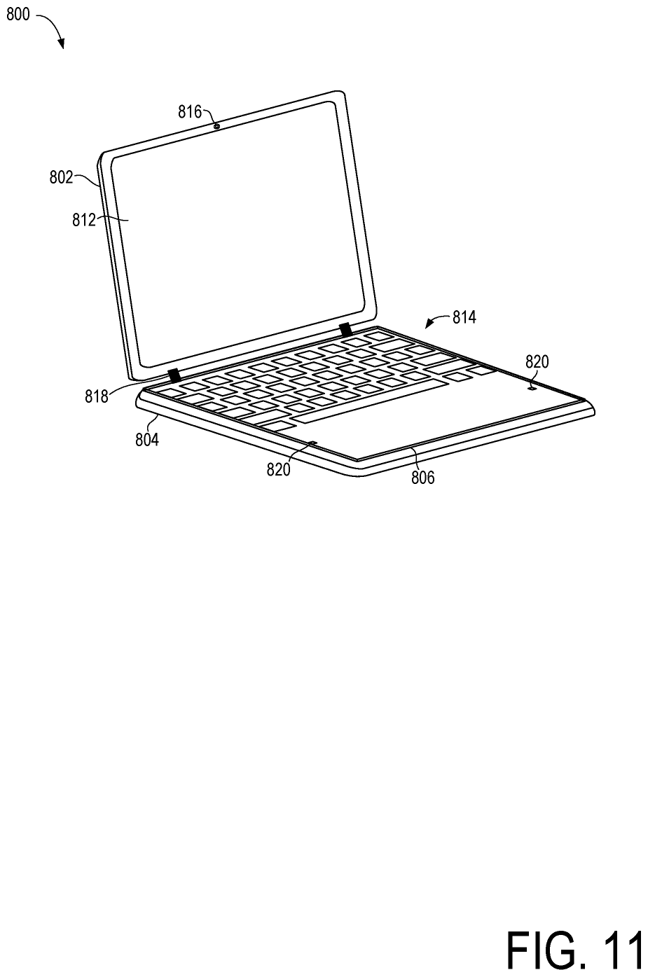

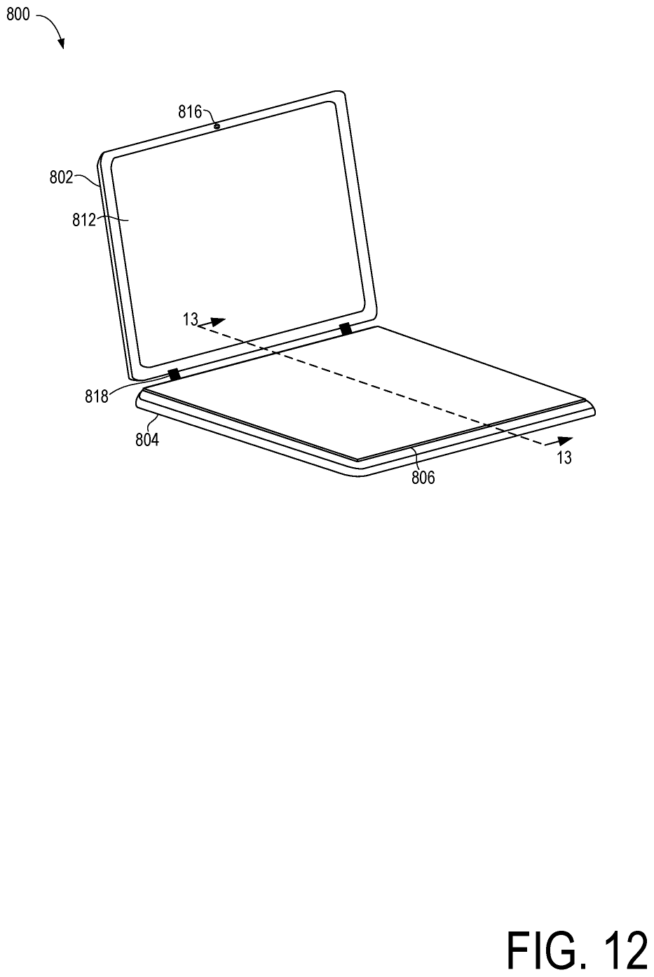

Referring now to FIGS. 8-12, an illustrative compute device 800 includes a lid portion 802 and a base portion 804. The lid portion 802 includes a display 812, and the base portion 804 includes a keyboard 814. The compute device 800 includes an overlay component 806. The overlay component 806 is movable between one position adjacent the lid portion 802, as shown in FIGS. 9 and 10, and another position adjacent the base portion 804, as shown in FIGS. 11 and 12. As discussed in more detail below, in the illustrative embodiment, the overlay component 806 is electrically switchable between an opaque state and a clear state. The overlay component 806 in a clear state is shown in FIGS. 9 and 11, and the overlay component in an opaque state is shown in FIGS. 10 and 12. In other embodiments, the overlay component 806 is passive, without any active electronic components. Such an overlay component 806 may include a coating to make it appear to have different opacity depending on a direction of view. For example, the coating may make the display 812 visible when the overlay component 806 is next to the display 812 and may make the overlay component 806 appear opaque or translucent when the overlay component 806 is next to the keyboard 814. A passive overlay component 806 may be simpler, more cost effective, and less prone to failure than one with active electronic components. In another embodiment, the overlay component 806 may have the same opacity in both directions, but the backlight of the display 812 allows the display 812 to be seen through the overlay component 806 when the overlay component 806 is next to the display 812. When the overlay component 806 is next to the keyboard 814, a backlight for the keyboard 814 may be turned off, causing the overlay component 806 to appear opaque or translucent, allowing the overlay component 806 to be used as a drawing surface.

In various embodiments and as described in more detail below, the overlay component 806 may include a touch sensor, a display such as an organic light-emitting diode (OLED) display, and/or a polarizer layer. A user may use the overlay component 806 as, e.g., a touch pad, a drawing surface, etc., either when the overlay component 806 is adjacent the lid portion 802 or when the overlay component 806 is adjacent the base portion 804. In some embodiments, the overlay component 806 may be used as a whiteboard-type surface along with standard dry-erase markers.

The illustrative compute device 800 is embodied as a laptop with a clamshell configuration. The illustrative compute device 800 can be in an open configuration (shown in FIGS. 8-12) or a closed configuration, with the lid portion 802 positioned on top of the base portion 804 with the display 812 facing downwards toward the base portion 804. Additionally or alternatively, the compute device 800 may be embodied as a laptop with additional configurations. For example, the compute device 800 may be a laptop with a display that can rotate up to 360°, allowing the compute device 800 to be in a book configuration, a tablet configuration, etc. The compute device 800 may be a 2-in-1 device, with a lid portion 802 that can separate from the base portion 804.

The illustrative lid portion 802 has a display 812. The display 812 may be any suitable size and/or resolution, such as a 5-18 inch display, with a resolution from 340×480 to 3820×2400. The display 812 may use any suitable display technology, such as LED, OLED, QD-LED, electronic paper display, etc. The display 812 may be a touchscreen display. The lid portion 802 may also include a camera 816. The camera 816 may include one or more fixed or adjustable lenses and one or more image sensors. The image sensors may be any suitable type of image sensors, such as a CMOS or CCD image sensor. The camera 816 may have any suitable aperture, focal length, field of view, etc. For example, the camera 816 may have a field of view of 60-810° in the azimuthal and/or elevation directions. In some embodiments, the camera 816 has a field of view that can capture the entire overlay component 806 when the overlay component is adjacent the base portion 104.

In the illustrative embodiment, the base portion 804 is connected to the lid portion 802 by one or more hinges 818. The overlay component 106 may also be connected to the hinges 818. In some embodiment, the overlay component 106 may be connected using a different set of hinges or may otherwise be connected in a different manner. In the illustrative embodiment, the base portion 804 may include overlay sensors 820 that are configured to sense the position of the overlay component 806, such as by detecting magnets in the overlay component 806. In some embodiments, the base portion 804 and/or the lid portion 802 may include one or more magnets that attract magnets in the overlay component 806 to hold the overlay component 806 in place. In some embodiments, the overlay sensors 820 may sense the position of the overlay component 806 in other ways, such as by reading an RFID tag, monitoring a light level, etc. In other embodiments, the position of the overlay component 806 may not be automatically sensed by the compute device 800. Rather, a user may manually indicate to the compute device 800 that the overlay component 806 is adjacent the lid portion 802 or the base portion 804, or the compute device 800 may not be aware of whether the overlay component 806 is adjacent the lid portion 802 or the base portion 804.

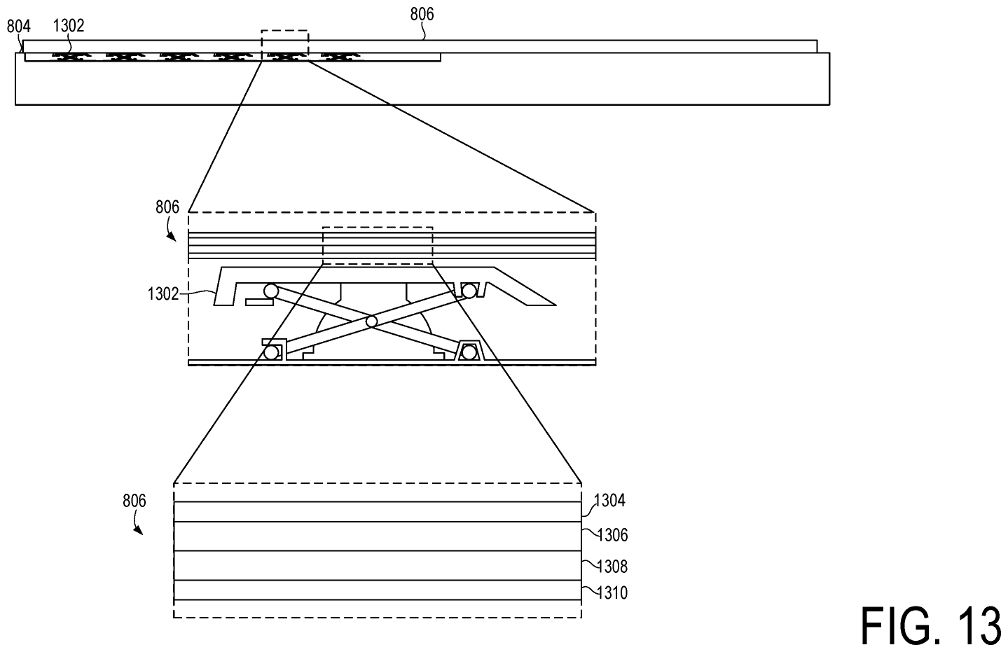

Referring now to FIG. 13, in one embodiment, a cross-sectional view of the base portion 804 is shown with the overlay component 806 adjacent the base portion 804, above the keys 1302 of the keyboard 814. As shown in the inset, the overlay component 806 includes several layers. In one embodiment, the overlay component 806 includes a top cover 1304, a touch layer 1306, an electrically-switchable opaque/transparent layer 1308, and a bottom cover 1310. The overlay component 806 may also include additional layers not shown, such as support layers, adhesive layers, etc. The top cover 1304 and the bottom cover 1310 may be any suitable material, such as hardened glass or plastic (e.g., polyimide or other polymer). The mechanical (e.g., hardness) and surface properties (e.g., roughness, friction coefficient, coatings) may be chosen based on usage needs. The touch layer 1306 may be any suitable touch layer, such as a capacitive touch layer. The electrically-switchable opaque/transparent layer 1308 may be any suitable material that can be electrically switched between being opaque and transparent. In the illustrative embodiment, the electrically-switchable opaque/transparent layer 1308 is polymer-dispersed liquid crystal (PDLC). In the illustrative embodiment, when a voltage is applied across the PDLC layer 1308, liquid crystals are aligned, allowing light to pass through. When a voltage across the PDLC layer 1308 is removed, the liquid crystals being randomly dispersed, scattering light and being opaque. The overlay component 806 may have any suitable thickness, such as 0.5-3 millimeters.

In the illustrative embodiment, the electrically-switchable opaque/transparent layer 1308 may be switched automatically from transparent when the overlay component 806 is adjacent the lid portion 802 to opaque when the overlay component 806 is adjacent the base portion 804. In such an embodiment, when the overlay component 806 is adjacent the lid portion 802, the display 812 can be viewed through the transparent overlay component 806, and the keyboard 814 is accessible. In some embodiments, a user may be able to select transparency of the overlay component 806. When the overlay component 806 is adjacent the base portion 804, a user can, e.g., provide touch input on the overlay component 806, draw on the overlay component 806, etc.

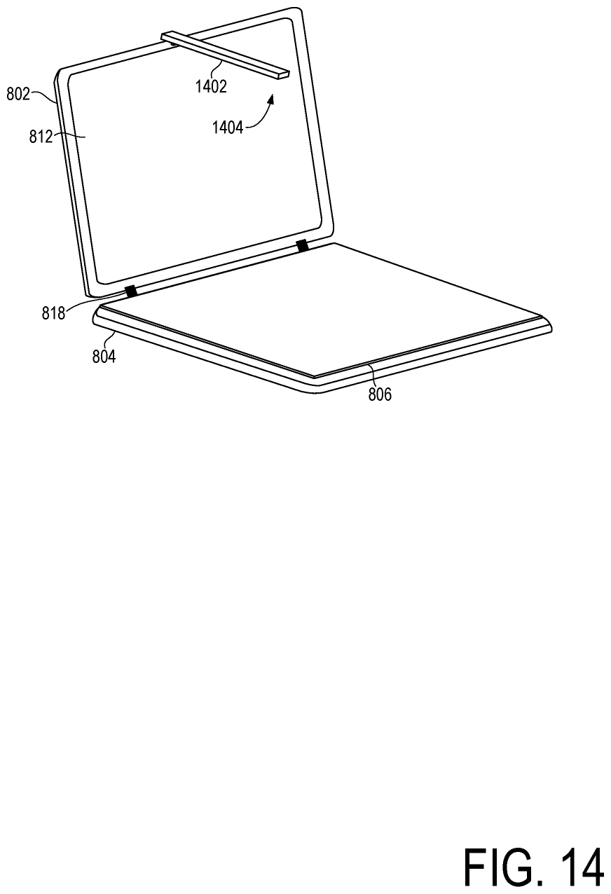

Referring now to FIG. 14, in one embodiment, a camera 1404 may be positioned on the underside of an extension arm 1402, allowing the camera 1404 to view the overlay component 806. Such a configuration may allow a user to capture images or video of drawings on the overlay component 806. The extension arm 1402 may be attachable to the lid portion 802. In some embodiments, the camera 816 may be able to swivel to view the overlay component 806 when it is adjacent the base portion 804.

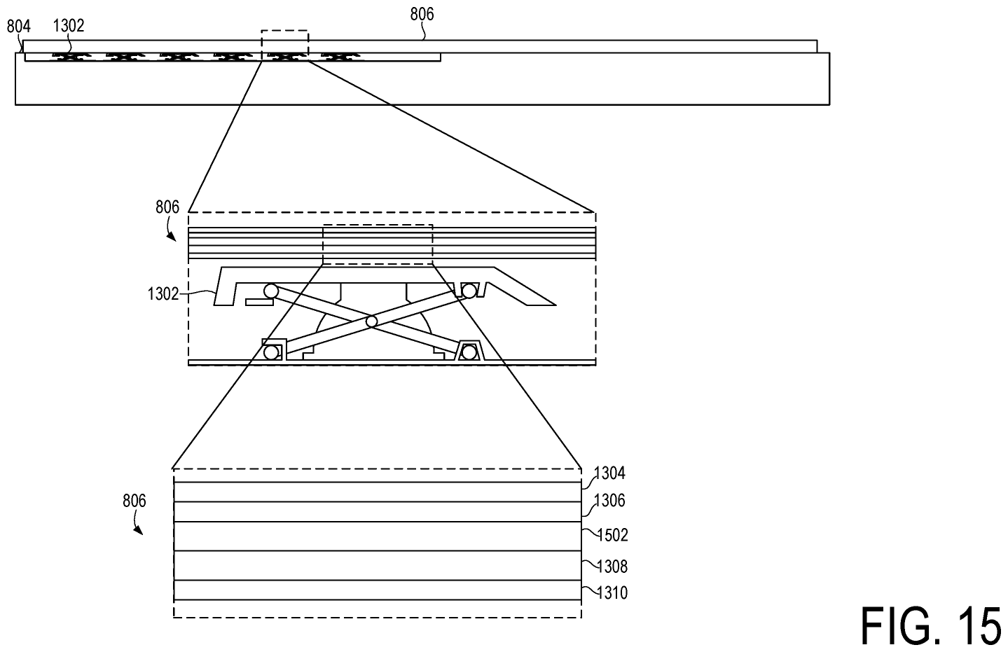

Referring now to FIG. 15, in one embodiment, an overlay component 806 may include a transparent display layer 1502, such as an OLED layer 1502. In the illustrative embodiment, the display layer 1502 is between the touch layer 1306 and the electrically-switchable opaque/transparent layer 1308. The display layer 1502 may allow the overlay component 806 to be used as a display in addition to or in place of the display 812.

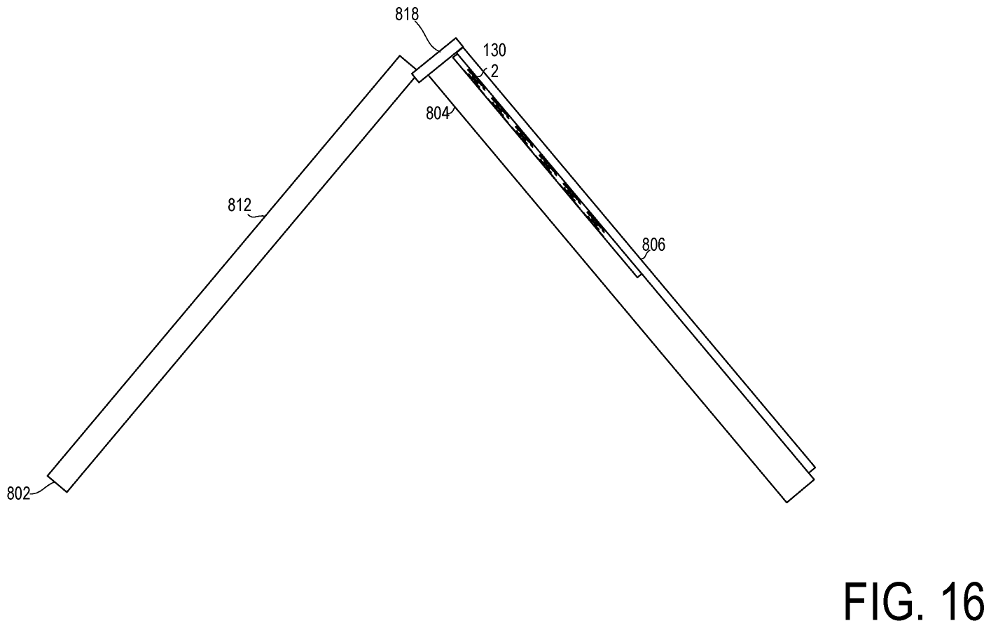

Referring now to FIG. 16, in one embodiment, the compute device 800 can be used in a tent configuration as shown. The compute device 800 includes an overlay component 806 with an OLED layer 1502, allowing both the lid portion 802 and the base portion 804 to be used to show video or other display images at the same time.

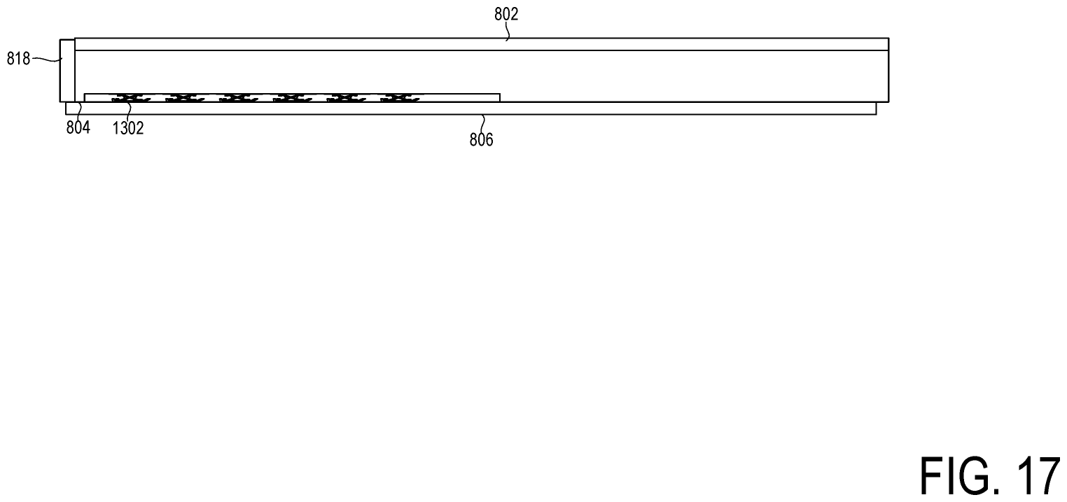

Referring now to FIG. 17, in one embodiment, the base portion 804 of the compute device 800 can be rotated 360° relative to the lid portion 802 as shown, placing the compute device 800 into a tablet configuration. As the overlay component 806 covers the keyboard 114, the user may have a more comfortable experience. In some embodiments, the OLED layer 1502 may allow the overlay component 806 to be used as a display when the compute device 100 is in the tablet configuration.

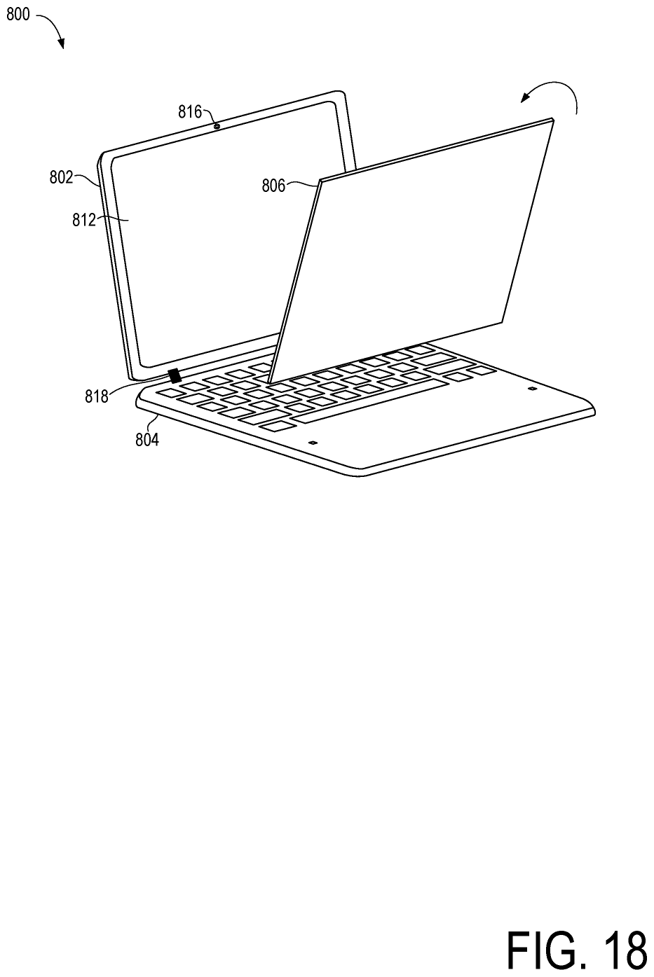

Referring now to FIG. 18, in one embodiment, the overlay component 806 with an OLED layer 1502 may be removable from the compute device 800. Such a configuration would allow for the overlay component 806 to be used as a display when adjacent the lid portion 802, then removed, rotated, and placed on the base portion 804, where it can also be used as a display. In some embodiments, the overlay component 806 may be used as a traditional OLED display for the compute device 100, and the display 812 may be an electrophoretic electronic paper display. Additionally or alternatively, the overlay component 806 may include an electronic paper display layer.

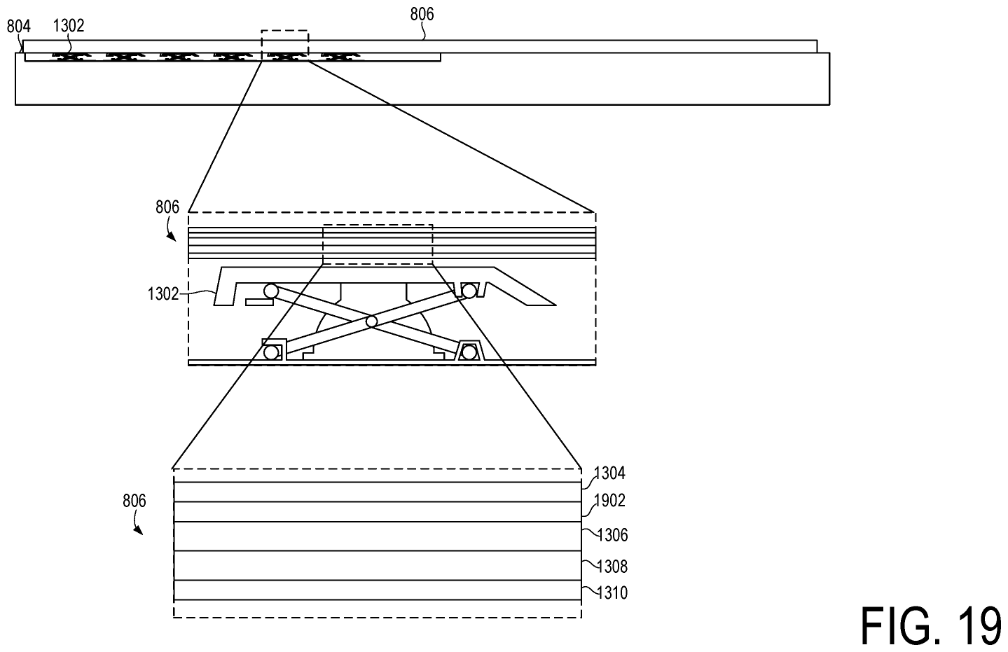

Referring now to FIG. 19, in one embodiment, an overlay component 806 may include a polarizer layer 1902. In the illustrative embodiment, the polarizer layer 1902 is between the top cover 1304 and the touch layer 1306. The polarizer layer 1902 may allow the field of view through the overlay component 806 to be controlled using the PDLC layer 1308, allowing the field of view of the display 812 to be controlled by applying voltage to the PDLC layer 1308.

It should be appreciated that additional embodiments of the overlay component 806 are envisioned beyond the specific layer structures shown in FIGS. 13, 15, and 19. For example, in one embodiment, the overlay component 806 may not include a touch layer 1306 and/or a PDLC layer 1308. In some embodiments, the overlay component 806 may only include, e.g., a top cover 1304 and/or a bottom cover 1310. In some embodiments, one of the layers, such as the polarizer layer 1902, the touch layer 1306, the PDLC layer 1308, the top cover 1304, or the bottom cover 1310 may have a one-way coating on it. The one-way coating may be reflective or non-reflective. The one-way coating may allow for the display 812 to be viewed when the overlay component 806 is adjacent the display 812 and also cause the overlay component 806 to appear opaque or translucent when the overlay component is adjacent the keyboard 814. In some embodiments, the overlay component 806 may have a top surface that, when it is against the display 812, allows the display to be seen through the overlay component 806. In such an embodiment, when the overlay component is next to the keyboard 114, the top surface may appear opaque or translucent, allowing it to be used as a drawing surface.

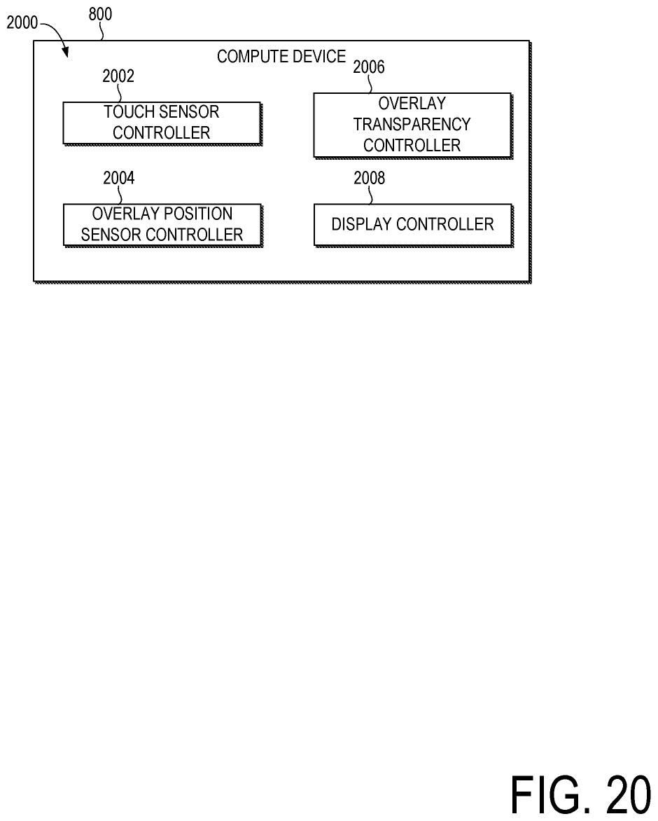

Referring now to FIG. 20, in an illustrative embodiment, the compute device 800 establishes an environment 2000 during operation. The illustrative environment 2000 includes a touch sensor controller 2002, an overlay position sensor controller 2004, an overlay transparency controller 2006, and a display controller 2008. The various modules of the environment 2000 may be embodied as hardware, software, firmware, or a combination thereof. For example, the various modules, logic, and other components of the environment 2000 may form a portion of, or otherwise be established by, the processor 602, the memory 604, the data storage 608, or other hardware components of the compute device 800. As such, in some embodiments, one or more of the modules of the environment 2000 may be embodied as circuitry or collection of electrical devices (e.g., touch sensor controller circuitry 2002, overlay position sensor controller circuitry 2004, overlay transparency controller circuitry 2006, display controller circuitry 2008, etc.). It should be appreciated that, in such embodiments, one or more of the circuits (e.g., the touch sensor controller circuitry 2002, the overlay position sensor controller circuitry 2004, the overlay transparency controller circuitry 2006, the display controller circuitry 2008, etc.) may form a portion of one or more of the processor 602, the memory 604, the I/O subsystem 606, the data storage 608, and/or other components of the compute device 800. For example, in some embodiments, some or all of the modules may be embodied as the processor 602, as well as the memory 604 and/or data storage 608 storing instructions to be executed by the processor 602. Additionally, in some embodiments, one or more of the illustrative modules may form a portion of another module and/or one or more of the illustrative modules may be independent of one another. Further, in some embodiments, one or more of the modules of the environment 2000 may be embodied as virtualized hardware components or emulated architecture, which may be established and maintained by the processor 602 or other components of the compute device 800. It should be appreciated that some of the functionality of one or more of the modules of the environment 2000 may require a hardware implementation, in which case embodiments of modules that implement such functionality will be embodied at least partially as hardware.

The touch sensor controller 2002, which may be embodied as hardware, firmware, software, virtualized hardware, emulated architecture, and/or a combination thereof as discussed above, is configured to sense touches and/or hover positions of objects such as a stylus or finger of a user. The touch sensor controller 2002 may sense touches and hovers over or on the overlay component 806 when the overlay component 806 is either adjacent the lid portion 802 or adjacent the base portion 804. In some embodiments, the touch sensor coordinates may be remapped based on whether the overlay component 806 is adjacent the lid portion 802 or adjacent the base portion 804.

The overlay position sensor controller 2004, which may be embodied as hardware, firmware, software, virtualized hardware, emulated architecture, and/or a combination thereof as discussed above, is configured to sense the position of the overlay component 806. The overlay position sensor controller 2004 is configured to interface with the overlay sensors 820 that sense the position of the overlay component 806. The overlay position sensor controller 2004 may provide an indication to other components of the compute device 100, which may then change function based on the overlay component 806 being adjacent the lid portion 802 or adjacent the base portion 804. For example, a particular application, input interface, or display parameter may be changed in response to the overlay component 806 being changed from adjacent the lid portion 802 to adjacent the base portion 804 or vice versa. In some embodiments, a keyboard backlight layer 516 of the keyboard 814 may be turned off when the overlay component 806 is moved to adjacent the base portion 804.

The overlay transparency controller 2006, which may be embodied as hardware, firmware, software, virtualized hardware, emulated architecture, and/or a combination thereof as discussed above, is configured to control the transparency of the overlay component 806. For example, the overlay transparency controller 2006 may automatically turn the overlay component 806 opaque when it is placed adjacent the base portion 804 and may automatically turn the overlay component 806 transparent when it is placed adjacent the lid portion 802. In some embodiments, a user may be able to select whether the overlay component 806 is transparent. In some embodiments, the overlay transparency control 2006 may control transparency of the overlay component 806 to protect the privacy of the user. For example, the overlay transparency controller 2006 may be able to identify a user of the compute device 800. In some embodiments, the overlay transparency controller 2006 may authenticate the user based on, e.g., a password or other credentials, face recognition or other biometrics, etc. The overlay transparency controller 2006 may monitor for the presence of the identified and/or authenticated user using the camera 116. If the user walks away, the overlay transparency controller 2006 may automatically turn the overlay component 806 opaque. Additionally or alternatively, if another user other than the identified and/or authenticated user moves into view of the display 812, the overlay transparency controller 2006 may automatically turn the overlay component 806 opaque.

The display controller 2008, which may be embodied as hardware, firmware, software, virtualized hardware, emulated architecture, and/or a combination thereof as discussed above, is configured to control the display 812 and/or a display on the overlay component 806. In one embodiment, the display controller 2008 may control when the overlay component 806 is opened and being used as an electronic paper display, the display 112 may be turned off to save power.

### EXAMPLES

Illustrative examples of the technologies disclosed herein are provided below. An embodiment of the technologies may include any one or more, and any combination of, the examples described below.

Example 1 includes a compute device comprising a lid comprising a display; a base portion comprising a keyboard; and an overlay component comprising a first overlay section and a second overlay section, wherein the second overlay section is movable between a first position adjacent a top surface of the first overlay section and a second position in which the second overlay section covers at least part of the keyboard.

Example 2 includes the subject matter of Example 1, and wherein the second overlay section comprises a first surface and a second surface opposite the first surface, wherein the base portion comprises a touch sensor, wherein the touch sensor is to sense touches on the first surface of the second overlay section in the first position and sense touches on the second surface of the second overlay section in the second position.

Example 3 includes the subject matter of any of Examples 1 and 2, and wherein the compute device is to interpret the touches on the first surface of the second overlay section in the first position as input on a track pad.

Example 4 includes the subject matter of any of Examples 1-3, and wherein the touch sensor is to detect hovers of one or more objects over the overlay component.

Example 5 includes the subject matter of any of Examples 1-4, and wherein the touch sensor comprises a metal grid in the base portion below the overlay component.

Example 6 includes the subject matter of any of Examples 1-5, and wherein the overlay component comprises a magnetic hinge.

Example 7 includes the subject matter of any of Examples 1-6, and wherein the magnetic hinge comprises one or more magnets in the first overlay section and one or more magnets in the second overlay section, wherein the one or more magnets in the first overlay section are attracted to the one or more magnets in the second overlay section along a first plane when the second overlay section is in the first position and along a second plane when the second overlay section is in the second position, the first plane substantially perpendicular to the second plane.

Example 8 includes the subject matter of any of Examples 1-7, and wherein the magnetic hinge results in a smooth transition between the first overlay section and the second overlay section.

Example 9 includes the subject matter of any of Examples 1-8, and wherein the overlay component does not include active electronic components.

Example 10 includes the subject matter of any of Examples 1-9, and wherein the overlay component comprises an electronic paper display.

Example 11 includes the subject matter of any of Examples 1-10, and wherein the compute device is to turn off the display in response to use of the electronic paper display.

Example 12 includes the subject matter of any of Examples 1-11, and wherein the first overlay section is a physically separate component from the second overlay section.

Example 13 includes the subject matter of any of Examples 1-12, and wherein the second overlay section comprises a first surface and a second surface opposite the first surface, wherein the first surface and the second surface are glass or ceramic.

Example 14 includes the subject matter of any of Examples 1-13, and further including one or more sensors to detect whether the second overlay section is in the first position or the second position.

Example 15 includes a method comprising receiving, by a compute device, data from an overlay sensor, the data indicative of a state of an overlay component, wherein the overlay component comprises a first overlay section and a second overlay section, wherein the second overlay section is movable between a first position in which the second overlay section is stacked on top of the first overlay section and a second position in which the second overlay section covers at least part of a keyboard of the compute device; determining, by the compute device, that the second overlay section is in the second position based on data received from the overlay sensor; receiving, by the compute device, data from a touch sensor of the compute device; and interpreting, by the compute device, the data from the touch sensor as a touch on or hover over the overlay component.

Example 16 includes the subject matter of Example 15, and wherein interpreting the data from the touch sensor as a touch on or hover over the overlay component comprises interpreting the data from the touch sensor as a touch on the overlay component based on a determination that the second overlay section is in the second position.

Example 17 includes the subject matter of any of Examples 15 and 16, and further including determining, by the compute device, a second position of the overlay component based on data from the sensor, wherein determining the second position of the overlay component comprises determining that the second overlay section is in the first position; receiving, by the compute device, additional data from the touch sensor; and interpreting, by the compute device, the additional data from the touch sensor as a hover over the keyboard based on a determination that the second overlay section is in the first position.

Example 18 includes the subject matter of any of Examples 15-17, and wherein the compute device comprises a lid and a base portion, wherein the base portion comprises the touch sensor.

Example 19 includes the subject matter of any of Examples 15-18, and wherein the second overlay section comprises a first surface and a second surface opposite the first surface, wherein the touch sensor is to sense touches on the first surface of the second overlay section when the second overlay section is in the first position and sense touches on the second surface of the second overlay section when the second overlay section is in the second position.

Example 20 includes the subject matter of any of Examples 15-19, and wherein the touch sensor is to sense hovers of one or more objects over the overlay component.

Example 21 includes the subject matter of any of Examples 15-20, and wherein the touch sensor comprises a metal grid in the base portion below the overlay component.

Example 22 includes the subject matter of any of Examples 15-21, and wherein the overlay component comprises a magnetic hinge.

Example 23 includes the subject matter of any of Examples 15-22, and wherein the magnetic hinge comprises one or more magnets in the first overlay section and one or more magnets in the second overlay section, wherein the one or more magnets in the first overlay section are attracted to the one or more magnets in the second overlay section when the second overlay section is in the first position and when the second overlay section is in the second position.

Example 24 includes the subject matter of any of Examples 15-23, and wherein the magnetic hinge does not require a seam between the first overlay section and the second overlay section.

Example 25 includes the subject matter of any of Examples 15-24, and wherein the overlay component does not include active electronic components.

Example 26 includes the subject matter of any of Examples 15-25, and wherein the overlay component comprises an electronic paper display.

Example 27 includes the subject matter of any of Examples 15-26, and wherein the compute device comprises a display in a lid, further comprising turning off the display in the lid in response to use of the electronic paper display.

Example 28 includes the subject matter of any of Examples 15-27, and wherein the first overlay section is not connected to the second overlay section.

Example 29 includes the subject matter of any of Examples 15-28, and wherein the first overlay section and the second overlay section are glass or ceramic.

Example 30 includes a compute device comprising a lid comprising a display; a base portion comprising a keyboard; and means for an overlay component that can unfold to at least partially cover the keyboard.

Example 31 includes the subject matter of Example 30, and wherein the base portion comprises means for sensing touches on the overlay component.

Example 32 includes the subject matter of any of Examples 30 and 31, and wherein the means for sensing touches is to sense touches on the overlay component is in a closed position and in an open position.

Example 33 includes the subject matter of any of Examples 30-32, and wherein the means for sensing touches is to sense hovers of one or more objects over the overlay component.

Example 34 includes the subject matter of any of Examples 30-33, and wherein the means for sensing touches comprises a metal grid in the base portion below the overlay component.

Example 35 includes the subject matter of any of Examples 30-34, and wherein the overlay component comprises means for seamless unfolding.

Example 36 includes the subject matter of any of Examples 30-35, and wherein the means for seamless unfolding comprises one or more magnets in a first overlay section and one or more magnets in a second overlay section, wherein the one or more magnets in the first overlay section are attracted to the one or more magnets in the second overlay along a first plane when the second overlay section is in the first position and along the second plane when the second overlay section is in the second position, the first plane substantially perpendicular to the second plane.

Example 37 includes the subject matter of any of Examples 30-36, and wherein the overlay component does not include active electronic components.

Example 38 includes the subject matter of any of Examples 30-37, and wherein the overlay component comprises an electronic paper display.

Example 39 includes the subject matter of any of Examples 30-38, and wherein the compute device is to turn off the display in response to use of the electronic paper display.

Example 40 includes the subject matter of any of Examples 30-39, and wherein the overlay component wherein the second overlay section comprises a first surface and a second surface opposite the first surface is glass or ceramic.

Example 41 includes the subject matter of any of Examples 30-40, and further including one or more sensors to detect whether the means for the overlay component is unfolded to at least partially cover the keyboard.

Example 42 includes one or more computer-readable media comprising a plurality of instructions stored thereon that, when executed by a compute device, causes the compute device to receive, from an overlay sensor of the compute device, data indicative of a state of an overlay component, wherein the overlay component comprises a first overlay section and a second overlay section, wherein the second overlay section is movable between a first position in which the second overlay section is stacked on top of the first overlay section and a second position in which the second overlay section covers at least part of a keyboard of the compute device; determine that the second overlay section is in the second position based on the data received from the overlay sensor; receive data from a touch sensor of the compute device; and interpret the data from the touch sensor as a touch on the overlay component based on a determination that the second overlay section is in the second position.

Example 43 includes the subject matter of Example 42, and wherein the plurality of instructions further cause the compute device to receive additional data from the overlay sensor; determine that the second overlay section is in the first position based on the additional data received from the overlay sensor; receive additional data from the touch sensor; and interpret the additional data from the touch sensor as a hover over the keyboard based on a determination that the second overlay section is in the first position.

Example 44 includes the subject matter of any of Examples 42 and 43, and wherein the compute device comprises a lid and a base portion, wherein the base portion comprises the touch sensor.

Example 45 includes the subject matter of any of Examples 42-44, and wherein the second overlay section comprises a first surface and a second surface opposite the first surface, wherein the plurality of instructions further cause the touch sensor to sense touches on the first surface of the second overlay section when the second overlay section is in the first position and sense touches on the second surface of the second overlay section when the second overlay section is in the second position.

Example 46 includes the subject matter of any of Examples 42-45, and wherein the plurality of instructions further cause the touch sensor to detect hovers of one or more objects over the overlay component.

Example 47 includes the subject matter of any of Examples 42-46, and wherein the touch sensor comprises a metal grid in the base portion below the overlay component.

Example 48 includes the subject matter of any of Examples 42-47, and wherein the overlay component comprises a magnetic hinge.

Example 49 includes the subject matter of any of Examples 42-48, and wherein the magnetic hinge comprises one or more magnets in the first overlay section and one or more magnets in the second overlay section, wherein the one or more magnets in the first overlay section are attracted to the one or more magnets in the second overlay section when the second overlay section is in the first position and when the second overlay section is in the second position.

Example 50 includes the subject matter of any of Examples 42-49, and wherein the magnetic hinge does not require a seam between the first overlay section and the second overlay section.

Example 51 includes the subject matter of any of Examples 42-50, and wherein the overlay component does not include active electronic components.

Example 52 includes the subject matter of any of Examples 42-51, and wherein the overlay component comprises an electronic paper display.

Example 53 includes the subject matter of any of Examples 42-52, and wherein the compute device comprises a display in a lid, wherein the plurality of instructions further cause the compute device to turn off the display in the lid in response to use of the electronic paper display.

Example 54 includes the subject matter of any of Examples 42-53, and wherein the first overlay section is not connected to the second overlay section.

Example 55 includes the subject matter of any of Examples 42-54, and wherein the first overlay section and the second overlay section are glass or ceramic.

Example 56 includes a compute device comprising a lid comprising a display; a base portion comprising a keyboard; a hinge that joins the lid and the base portion; and an overlay component, wherein the overlay component is movable between a first position adjacent the lid and a second position adjacent the base portion.

Example 57 includes the subject matter of Example 56, and wherein the overlay component is electrically switchable between an opaque state and a clear state.

Example 58 includes the subject matter of any of Examples 56 and 57, and wherein the overlay component comprises a polymer-dispersed liquid crystal (PDLC) layer.

Example 59 includes the subject matter of any of Examples 56-58, and wherein the overlay component comprises a polarizer, wherein the PDLC layer is able to electrically switch between a first field of view through the polarizer and a second field of view through the polarizer different from the first field of view.

Example 60 includes the subject matter of any of Examples 56-59, and further including one or more sensors to detect whether the overlay component is in the first position or the second position.

Example 61 includes the subject matter of any of Examples 56-60, and further including a processor; one or more computer-readable media comprising a plurality of instructions stored thereon that, when executed by the processor, cause the processor to turn the overlay component transparent in response to the overlay component being placed in the first position and turn the overlay component opaque in response to the overlay component being placed in the second position.

Example 62 includes the subject matter of any of Examples 56-61, and wherein a user of the compute device is able to select whether the overlay component is in the opaque state or in the clear state.

Example 63 includes the subject matter of any of Examples 56-62, and wherein the overlay component comprises a touch sensor layer.

Example 64 includes the subject matter of any of Examples 56-63, and further including a processor; one or more computer-readable media comprising a plurality of instructions stored thereon that, when executed by the processor, cause the processor to map touch sensor coordinates dependent on whether the overlay component is in the first position or the second position.

Example 65 includes the subject matter of any of Examples 56-64, and wherein the overlay component comprises a display layer.

Example 66 includes the subject matter of any of Examples 56-65, and wherein the display layer comprises an organic light-emitted diode (OLED) display.

Example 67 includes the subject matter of any of Examples 56-66, and wherein the compute device is able to display a first video on the display of the lid and a second video on the display layer of the overlay component simultaneously.

Example 68 includes the subject matter of any of Examples 56-67, and wherein the display layer is an electronic paper display.

Example 69 includes the subject matter of any of Examples 56-68, and further including a processor; and one or more computer-readable media comprising a plurality of instructions stored thereon that, when executed by the processor, cause the processor to determine that a user of the compute device is outside a field of view of a camera of the compute device; and switch the overlay component to the opaque state in response to the determination that the user is outside the field of view.

Example 70 includes the subject matter of any of Examples 56-69, and further including a processor; and one or more computer-readable media comprising a plurality of instructions stored thereon that, when executed by the processor, cause the processor to identify a user of the compute device; determine that a person that is other than the identified user of the compute device is visible in a field of view of a camera of the compute device; and switch the overlay component to the opaque state in response to the determination that the person other than the identified user is visible in the field of view.

Example 71 includes the subject matter of any of Examples 56-70, and wherein the overlay component comprises a top cover and a bottom cover.

Example 72 includes the subject matter of any of Examples 56-71, and wherein the top cover comprises glass or plastic.

Example 73 includes the subject matter of any of Examples 56-72, and further including a first set of one or more magnets to hold the overlay component in the first position and a second set of one or more magnets to hold the overlay component in the second position.

Example 74 includes the subject matter of any of Examples 56-73, and wherein the hinge allows the lid to rotate 360° relative to the base portion, wherein the hinge allows the overlay component to rotate at least 180° relative to the base portion.

Example 75 includes the subject matter of any of Examples 56-74, and wherein the overlay component does not include active electronic components.

Example 76 includes a method comprising moving an overlay component of a compute device from a first position to a second position, wherein the compute device comprises a lid comprising a display; a base portion comprising a keyboard; a hinge that joins the lid and the base portion; and the overlay component, wherein the first position is adjacent the lid and the second position is adjacent the base portion.

Example 77 includes the subject matter of Example 76, and wherein the overlay component does not include active electronic components. further comprising viewing the display through the overlay component when the overlay component is in the first position; and drawing on the overlay component when the overlay component is in the second position.

Example 78 includes the subject matter of any of Examples 76 and 77, and further including capturing, by a camera of the compute device, one or more images of the overlay component when the overlay component is in the second position.

Example 79 includes the subject matter of any of Examples 76-78, and further including determining, by the compute device, that the overlay component has been moved to the first position adjacent the lid of the compute device; configuring, by the compute device, the overlay component to be transparent in response to a determination that the overlay component has been moved to the first position; determining, by the compute device, that the overlay component has been moved to the second position adjacent the base portion of the compute device; and configuring, by the compute device, the overlay component to be opaque in response to a determination that the overlay component has been moved to the second position.

Example 80 includes the subject matter of any of Examples 76-79, and wherein the overlay component comprises a polymer-dispersed liquid crystal (PDLC) layer, wherein configuring the overlay component to be transparent comprises applying a voltage across the PDLC layer.

Example 81 includes the subject matter of any of Examples 76-80, and wherein determining that the overlay component has been moved to the first position comprises sensing the position of the overlay component using one or more sensors.

Example 82 includes the subject matter of any of Examples 76-81, and wherein the overlay component comprises a touch sensor layer.

Example 83 includes the subject matter of any of Examples 76-82, and wherein a user of the compute device is able to select whether the overlay component is in the opaque state or in the clear state.

Example 84 includes the subject matter of any of Examples 76-83, and further including mapping, by the compute device, touch sensor coordinates to a first mapping in response to the overlay component being placed in the first position; and mapping, by the compute device, touch sensor coordinates to a second mapping in response to the overlay component being placed in the second position.

Example 85 includes the subject matter of any of Examples 76-84, and wherein the overlay component comprises a display layer.

Example 86 includes the subject matter of any of Examples 76-85, and wherein the display layer comprises an organic light-emitted diode (OLED) display.

Example 87 includes the subject matter of any of Examples 76-86, and further including displaying, by the compute device, a first video on the display of the lid and a second video on the display layer of the overlay component simultaneously.

Example 88 includes the subject matter of any of Examples 76-87, and wherein the display layer is an electronic paper display.

Example 89 includes the subject matter of any of Examples 76-88, and further including determining, by the compute device, that a user of the compute device is not visible in a field of view of a camera of the compute device; and switching, by the compute device, the overlay component to be opaque in response to the determination that the user is not visible in the field of view.

Example 90 includes the subject matter of any of Examples 76-89, and further including determining, by the compute device, that a person that is not a user of the compute device is visible in a field of view of a camera of the compute device; and switching, by the compute device, the overlay component to be opaque in response to the determination that the person is visible in the field of view.

Example 91 includes the subject matter of any of Examples 76-90, and wherein the overlay component comprises a polarizer, wherein the overlay component is electrically switchable between a first field of view and a second field of view different from the first field of view.

Example 92 includes the subject matter of any of Examples 76-91, and wherein the overlay component comprises a top cover and a bottom cover.

Example 93 includes the subject matter of any of Examples 76-92, and wherein the top cover comprises glass or plastic.

Example 94 includes the subject matter of any of Examples 76-93, and wherein the lid is able to rotate 360° relative to the base portion, wherein the overlay component is able to rotate 360° relative to the base portion.

Example 95 includes the subject matter of any of Examples 76-94, and wherein the compute device comprises a first set of one or more magnets to hold the overlay component in the first position.

Example 96 includes a compute device comprising a lid comprising a display; a base portion comprising a keyboard; an overlay component, wherein the overlay component is movable between a first position adjacent the lid and a second position adjacent the base portion; and means for electrically switching the overlay component between an opaque state and a clear state.

Example 97 includes the subject matter of Example 96, and wherein the means for electrically switching the overlay component comprises a polymer-dispersed liquid crystal (PDLC) layer.

Example 98 includes the subject matter of any of Examples 96 and 97, and further including means for sensing whether the overlay component is in the first position or the second position.

Example 99 includes the subject matter of any of Examples 96-98, and wherein the compute device is to turn the overlay component transparent in response to the overlay component being placed in the first position and turn the overlay component opaque in response to the overlay component being placed in the second position.

Example 100 includes the subject matter of any of Examples 96-99, and wherein a user of the compute device is able to select whether the overlay component is in the opaque state or in the clear state.

Example 101 includes the subject matter of any of Examples 96-100, and wherein the overlay component comprises means for sensing touches on the overlay component.

Example 102 includes the subject matter of any of Examples 96-101, and wherein the compute device is to map touch sensor coordinates to a first mapping in response to the overlay component being placed in the first position and map touch sensor coordinates to a second mapping in response to the overlay component being placed in the second position.

Example 103 includes the subject matter of any of Examples 96-102, and wherein the overlay component comprises a top cover and a bottom cover.

Example 104 includes the subject matter of any of Examples 96-103, and wherein the top cover comprises glass or plastic.

Example 105 includes the subject matter of any of Examples 96-104, and further including a first means for holding the overlay component in the first position and a second means for holding the overlay component in the second position.

Example 106 includes the subject matter of any of Examples 96-105, and wherein the overlay component comprises a display layer.

Example 107 includes the subject matter of any of Examples 96-106, and wherein the display layer comprises an organic light-emitted diode (OLED) display.

Example 108 includes the subject matter of any of Examples 96-107, and wherein the compute device is able to display a first video on the display of the lid and a second video on the display layer of the overlay component simultaneously.

Example 109 includes the subject matter of any of Examples 96-108, and wherein the display of the display layer is an electronic paper display.

Example 110 includes the subject matter of any of Examples 96-109, and wherein the lid is able to rotate 360° relative to the base portion, wherein the overlay component is able to rotate 360° relative to the base portion.

Example 111 includes the subject matter of any of Examples 96-110, and further including means for determining that a user of the compute device is not visible in a field of view of a camera of the compute device; and means for switching the overlay component to the opaque state in response to the determination that the user is not visible in the field of view.

Example 112 includes the subject matter of any of Examples 96-111, and further including means for determining that a person that is not a user of the compute device is visible in a field of view of a camera of the compute device; and means for switching the overlay component to the opaque state in response to the determination that the person is visible in the field of view.

Example 113 includes the subject matter of any of Examples 96-112, and further including means for electrically switching the overlay component between a first field of view and a second field of view different from the first field of view.

Example 114 includes one or more computer-readable media comprising a plurality of instructions stored thereon that, when executed, causes a compute device to determine that an overlay component has been moved to a first position adjacent a lid of the compute device; configure the overlay component to be transparent in response to a determination that the overlay component has been moved to the first position; determine that the overlay component has been moved to a second position adjacent a base portion of the compute device; and configure the overlay component to be opaque in response to a determination that the overlay component has been moved to the second position.

Example 115 includes the subject matter of Example 114, and wherein the overlay component comprises a polymer-dispersed liquid crystal (PDLC) layer, wherein to configure the overlay component to be transparent comprises to apply a voltage across the PDLC layer.

Example 116 includes the subject matter of any of Examples 114 and 115, and wherein to determine that the overlay component has been moved to the first position comprises to sense the position of the overlay component using one or more sensors.

Example 117 includes the subject matter of any of Examples 114-116, and wherein the plurality of instructions further causes the compute device to control whether the overlay component is in the opaque state or in the clear state based on an input from a user of the compute device.

Example 118 includes the subject matter of any of Examples 114-117, and wherein the overlay component comprises a touch sensor layer.

Example 119 includes the subject matter of any of Examples 114-118, and wherein the plurality of instructions further causes the compute device to map touch sensor coordinates to a first mapping in response to the overlay component being placed in the first position; and map touch sensor coordinates to a second mapping in response to the overlay component being placed in the second position.

Example 120 includes the subject matter of any of Examples 114-119, and wherein the overlay component comprises a top cover and a bottom cover.

Example 121 includes the subject matter of any of Examples 114-120, and wherein the top cover comprises glass or plastic.

Example 122 includes the subject matter of any of Examples 114-121, and wherein the compute device comprises a first set of one or more magnets to hold the overlay component in the first position and a second set of one or more magnets to hold the overlay component in the second position.

Example 123 includes the subject matter of any of Examples 114-122, and wherein the overlay component comprises a display layer.

Example 124 includes the subject matter of any of Examples 114-123, and wherein the display layer comprises an organic light-emitted diode (OLED) display.

Example 125 includes the subject matter of any of Examples 114-124, and wherein the plurality of instructions further causes the compute device to display a first video on the display of the lid and a second video on the display layer of the overlay component simultaneously.

Example 126 includes the subject matter of any of Examples 114-125, and wherein the display of the display layer is an electronic paper display.

Example 127 includes the subject matter of any of Examples 114-126, and wherein the lid is able to rotate 360° relative to the base portion, wherein the overlay component is able to rotate 360° relative to the base portion.

Example 128 includes the subject matter of any of Examples 114-127, and wherein the plurality of instructions further causes the compute device to determine that a user of the compute device is not visible in a field of view of a camera of the compute device; and switch the overlay component to be opaque in response to the determination that the user is not visible in the field of view.

Example 129 includes the subject matter of any of Examples 114-128, and wherein the plurality of instructions further causes the compute device to determine that a person that is not a user of the compute device is visible in a field of view of a camera of the compute device; and switch the overlay component to be opaque in response to the determination that the person is visible in the field of view.

Example 130 includes the subject matter of any of Examples 114-129, and wherein the overlay component comprises a polarizer, wherein the overlay component is electrically switchable between a first field of view and a second field of view different from the first field of view.

1. A compute device comprising:
a lid comprising a display;
a base portion comprising a keyboard;
a hinge that joins the lid and the base portion; and
an overlay component, wherein the overlay component is movable between a first position adjacent the lid and a second position adjacent the base portion.

2. The compute device of claim 1, wherein the overlay component is electrically switchable between an opaque state and a clear state.

3. The compute device of claim 2, wherein the overlay component comprises a polymer-dispersed liquid crystal (PDLC) layer.

4. The compute device of claim 3, wherein the overlay component comprises a polarizer, wherein the PDLC layer is able to electrically switch between a first field of view through the polarizer and a second field of view through the polarizer different from the first field of view.

5. The compute device of claim 2, further comprising one or more sensors to detect whether the overlay component is in the first position or the second position.

6. The compute device of claim 2, further comprising:
a processor;
one or more computer-readable media comprising a plurality of instructions stored thereon that, when executed by the processor, cause the processor to turn the overlay component transparent in response to the overlay component being placed in the first position and turn the overlay component opaque in response to the overlay component being placed in the second position.

7. The compute device of claim 2, wherein a user of the compute device is able to select whether the overlay component is in the opaque state or in the clear state.

8. The compute device of claim 2, wherein the overlay component comprises a touch sensor layer.

9. The compute device of claim 8, further comprising:
a processor;
one or more computer-readable media comprising a plurality of instructions stored thereon that, when executed by the processor, cause the processor to map touch sensor coordinates dependent on whether the overlay component is in the first position or the second position.

10. The compute device of claim 2, wherein the overlay component comprises a display layer.

11. The compute device of claim 10, wherein the display layer is an electronic paper display.

12. The compute device of claim 2, further comprising:
a processor;
one or more computer-readable media comprising a plurality of instructions stored thereon that, when executed by the processor, cause the processor to:
identify a user of the compute device;
determine that a person other than the identified user of the compute device is visible in a field of view of a camera of the compute device; and
switch the overlay component to the opaque state in response to the determination that the person other than the identified user is visible in the field of view.

13. The compute device of claim 1, further comprising a first set of one or more magnets to hold the overlay component in the first position.

14. The compute device of claim 1, wherein the hinge allows the lid to rotate 360° relative to the base portion, wherein the hinge allows the overlay component to rotate at least 180° relative to the base portion.

15. The compute device of claim 1, wherein the overlay component does not include active electronic components.

16. A method comprising:
moving an overlay component of a compute device from a first position to a second position,
wherein the compute device comprises:
a lid comprising a display;
a base portion comprising a keyboard;
a hinge that joins the lid and the base portion; and
the overlay component,
wherein the first position is adjacent the lid and the second position is adjacent the base portion.

17. The method of claim 16, wherein the overlay component does not include active electronic components. further comprising:
viewing the display through the overlay component when the overlay component is in the first position; and
drawing on the overlay component when the overlay component is in the second position.

18. The method of claim 17, further comprising capturing, by a camera of the compute device, one or more images of the overlay component when the overlay component is in the second position.

19. The method of claim 16, further comprising:
determining, by the compute device, that the overlay component has been moved to the first position adjacent the lid of the compute device;
configuring, by the compute device, the overlay component to be transparent in response to a determination that the overlay component has been moved to the first position;
determining, by the compute device, that the overlay component has been moved to the second position adjacent the base portion of the compute device; and
configuring, by the compute device, the overlay component to be opaque in response to a determination that the overlay component has been moved to the second position.

20. The method of claim 19, wherein the overlay component comprises a polymer-dispersed liquid crystal (PDLC) layer, wherein configuring the overlay component to be transparent comprises applying a voltage across the PDLC layer.

21. The method of claim 19, wherein the compute device comprises a first set of one or more magnets to hold the overlay component in the first position.

22. One or more computer-readable media comprising a plurality of instructions stored thereon that, when executed, causes a compute device to:
determine that an overlay component has been moved to a first position adjacent a lid of the compute device;
configure the overlay component to be transparent in response to a determination that the overlay component has been moved to the first position;
determine that the overlay component has been moved to a second position adjacent a base portion of the compute device; and
configure the overlay component to be opaque in response to a determination that the overlay component has been moved to the second position.

23. The one or more computer-readable media of claim 22, wherein the overlay component comprises a polymer-dispersed liquid crystal (PDLC) layer, wherein to configure the overlay component to be transparent comprises to apply a voltage across the PDLC layer.

24. The one or more computer-readable media of claim 22, wherein to determine that the overlay component has been moved to the first position comprises to sense the position of the overlay component using one or more sensors.

25. The one or more computer-readable media of claim 22, wherein the plurality of instructions further causes the compute device to:
determine that a person that is not a user of the compute device is visible in a field of view of a camera of the compute device; and
switch the overlay component to be opaque in response to the determination that the person is visible in the field of view.
